(19) United States
(12) Patent Application Publication
(10) Pub. No.: US 2025/0279396 A1
(43) Pub. Date: Sep. 4, 2025

(54) SEMICONDUCTOR DEVICE AND METHOD OF ARRANGING AN INTERFACE OF A SEMICONDUCTOR DEVICE

(71) Applicants: Global Unichip Corporation, Hsinchu (TW); Taiwan Semiconductor Manufacturing Company, Ltd., Hsinchu (TW)

(72) Inventors: Igor Elkanovich, Hsinchu (TW); Yung-Chih Chen, Hsinchu (TW); Chih-Kang Chiu, Hsinchu (TW)

(73) Assignees: Global Unichip Corporation, Hsinchu (TW); Taiwan Semiconductor Manufacturing Company, Ltd., Hsinchu (TW)

(21) Appl. No.: 18/590,957

(22) Filed: Feb. 29, 2024

(51) Int. Cl. H01L 25/065; H01L 23/00; H01L 25/00; H01Q 1/22; H04B 1/40

(52) U.S. Cl. CPC H01L 25/0657; H01L 24/08; H01L 24/16; H01L 24/81; H01L 25/50; H01L 2224/08145; H01L 2224/16145; H01L 2224/8136; H01L 2924/1437; H01Q 1/2283; H04B 1/40

(57) ABSTRACT

A semiconductor device including a first semiconductor die and a second semiconductor die is provided. The first semiconductor die includes a first substrate, a first interface circuit and first bonding components. The first bonding components are arranged in a first bond array region and the first interface circuit is arranged inside the first bond array region. The second semiconductor die includes a second substrate, a second interface circuit and second bonding components. The first bonding components are connected to the second bonding components, the first interface circuit and the second interface circuit are located between the first substrate and the second substrate, and the first semiconductor die and the second semiconductor die are interlinked by an 10 interface constructed by the first interface circuit, the first bonding components, the second interface circuit and the second bonding components. A method of arranging an interface of a semiconductor device is also provided herein.

### BACKGROUND

### Technical Field

The disclosure is related to a semiconductor device and a method of arranging an interface of a semiconductor device.

### Description of Related Art

With the development of the semiconductor industry, semiconductor devices enable more and more functions by the increase of integration. To achieve high integration, the interface for interlinking two or more semiconductor dies is required and the arrangement of the interface becomes one of the indispensable parts in IC (integrated circuit) design and manufacture.

### SUMMARY

The disclosure is directed to a semiconductor device including an interface interlinking between two semiconductor dies with a flexible design on the arrangement of bonding components and interface circuits.

According to embodiments of the disclosure, a semiconductor device includes a first semiconductor die and a second semiconductor die. The first semiconductor die includes a first substrate, a first interface circuit and first bonding components, wherein the first bonding components are arranged in a first bond array region and the first interface circuit is arranged inside the first bond array region. The second semiconductor die includes a second substrate, a second interface circuit and second bonding components. The first bonding components are connected to the second bonding components, the first interface circuit and the second interface circuit are located between the first substrate and the second substrate, and the first semiconductor die and the second semiconductor die are interlinked by an interface constructed by the first interface circuit, the first bonding components, the second interface circuit and the second bonding components.

According to embodiments of the disclosure, the first interface circuit includes an interface logic circuit, transceivers and receivers, and the interface logic circuit, the transceivers and the receivers are arranged inside the first bond array region. The transceivers and the receivers are electrically connected to the first bonding components, respectively. A pitch of the transceivers and the receivers is smaller than a pitch of the first bonding components.

According to embodiments of the disclosure, a portion of the first interface circuit overlaps one or more of the first bonding components.

According to embodiments of the disclosure, the first semiconductor die further includes function circuit, the function circuit is in signal communication to the first interface circuit. A portion of the function circuit is arranged inside the first bond array region.

According to embodiments of the disclosure, the first semiconductor die further includes an interconnect wiring structure disposed between the first bonding components and the first interface circuit.

According to embodiments of the disclosure, the first bonding components and the second bonding components includes bonding pads, micro bumps or other types of 3D interconnection component.

According to embodiments of the disclosure, the second bonding components are arranged in a second bond array region substantially mirrored from the first bond array region. The second interface circuit is arranged inside the second bond array region. The second interface circuit includes an interface logic circuit, transceivers and receivers, and the interface logic circuit, the transceivers and the receivers are arranged inside the second bond array region. The transceivers and the receivers are electrically connected to the second bonding components, respectively. A pitch of the transceivers and the receivers is smaller than a pitch of the second bonding components.

According to embodiments of the disclosure, a portion of the second interface circuit overlaps one or more of the second bonding components.

According to embodiments of the disclosure, the second semiconductor die further includes a function circuit, and the function circuit is in signal communication to the second interface circuit. A portion of the function circuit is arranged inside a second bond array region of the second bonding components.

According to embodiments of the disclosure, the second semiconductor die further includes an interconnect wiring structure disposed between the second bonding components and the second interface circuit.

According to embodiments of the disclosure, a method of arranging an interface of a semiconductor device includes providing a first bond array region for arranging first bonding components implemented in a first semiconductor die; providing a first interface circuit implemented inside the first bond array region in the first semiconductor die; providing a second interface circuit and second bonding components implemented in a second semiconductor die; and bonding the first bonding components to the second bonding components.

According to embodiments of the disclosure, the first interface circuit includes an interface logic circuit, transceivers and receivers, and the interface logic circuit, the transceivers and the receivers are arranged inside the first bond array region. The transceivers and the receivers are electrically connected to the first bonding components, respectively, and a pitch of the transceivers and the receivers is smaller than a pitch of the first bonding components.

According to embodiments of the disclosure, the second bonding components are arranged in a second bond array region substantially mirrored from the first bond array region.

The second interface circuit includes an interface logic circuit, transceivers and receivers, and the interface logic circuit, the transceivers and the receivers are arranged inside the second bond array region. The transceivers and the receivers are electrically connected to the second bonding components, respectively, and a pitch of the transceivers and the receivers is smaller than a pitch of the second bonding components.

According to embodiments of the disclosure, a function circuit is further provided to be implemented inside the first bond array region in the first semiconductor die.

According to embodiments of the disclosure, a function circuit is further provided to be implemented in the second semiconductor die.

In light of the above, the semiconductor device includes semiconductor dies boded to each other in a face-to-face manner. The interface between the semiconductor dies include respective interface circuits and bonding components on each semiconductor die while the respective interface circuits are arranged inside the respective bond array regions of the bonding components. Accordingly, the interface circuit is able to be compatible to various pitch designs of the bonding components and the substrate implemented with the interface circuit may have more flexibility on spacing design.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 schematically illustrates a stack structure of a semiconductor device with the communication mechanism of the interface, according to an embodiment of the invention.

FIG. 2 schematically illustrates a communication mechanism of the interface between the first semiconductor die and an adjacent second semiconductor die, according to an embodiment of the invention.

FIG. 3 schematically illustrates an interface interlinking between the first semiconductor die and an adjacent second semiconductor die, according to an embodiment of the invention.

FIG. 4 schematically illustrates the arrangement of the interface for the semiconductor device in accordance with some embodiments of the disclosure.

FIG. 5 and FIG. 6 schematically illustrate the arrangements of the interface circuit and the bonding components in accordance with some embodiments of the disclosure.

FIG. 7 schematically illustrates a portion of a semiconductor die in a cross-section view in accordance with some embodiments of the disclosure.

FIG. 8 schematically illustrates a semiconductor device in a cross-sectional view in accordance with some embodiments of the disclosure.

### DESCRIPTION OF THE EMBODIMENTS

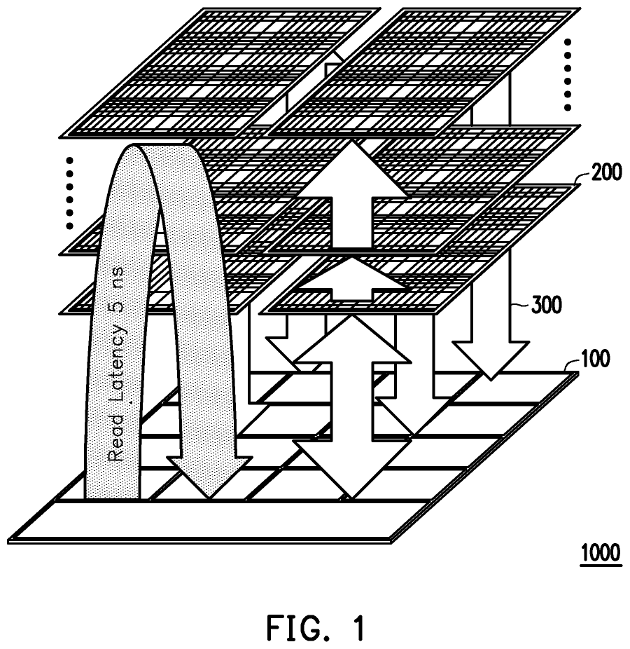

FIG. 1 schematically illustrates a stack structure of a semiconductor device with the communication mechanism of the interface, according to an embodiment of the invention. Referring to FIG. 1, a semiconductor device 1000 includes a first semiconductor die 100 and multiple second semiconductor dies 200 and an interface 300 linking the first semiconductor die 100 to the second semiconductor dies 200. The first semiconductor die 100, such as a processor semiconductor die, is included as a base semiconductor die in the semiconductor device 1000. The second semiconductor dies 200, such as SRAM semiconductor dies, are stacked over the first semiconductor die 100. The interface 300 is configured to communication with the information/data/signal between the first semiconductor die 100 and the second semiconductor dies 200. In some embodiments, the interface 300 interlinking the first semiconductor die 100 to an adjacent second semiconductor die 200 may also be referred as Glink-3D which achieves the interlink between semiconductor dies in a 3D package structure.

In some embodiments, the first semiconductor die 100 of processor has a command to access the data stored the second semiconductor die 200 of SRAM. The first semiconductor die 100 may be considered as a master semiconductor die and the second semiconductor dies 200 may be considered as slave semiconductor dies, but the disclosure is not limited thereto. Due to the interface 300 as implemented, the read latency may be controlled to be about constant and small, such 2 ns or 5 ns in the examples. A single clock is used in the interface 300 to distribute to all the second semiconductor dies 200, the path length from the first semiconductor die 100 to each second semiconductor die 200 is about the same and reliable. The latency can be adjusted to be about constant as predictable.

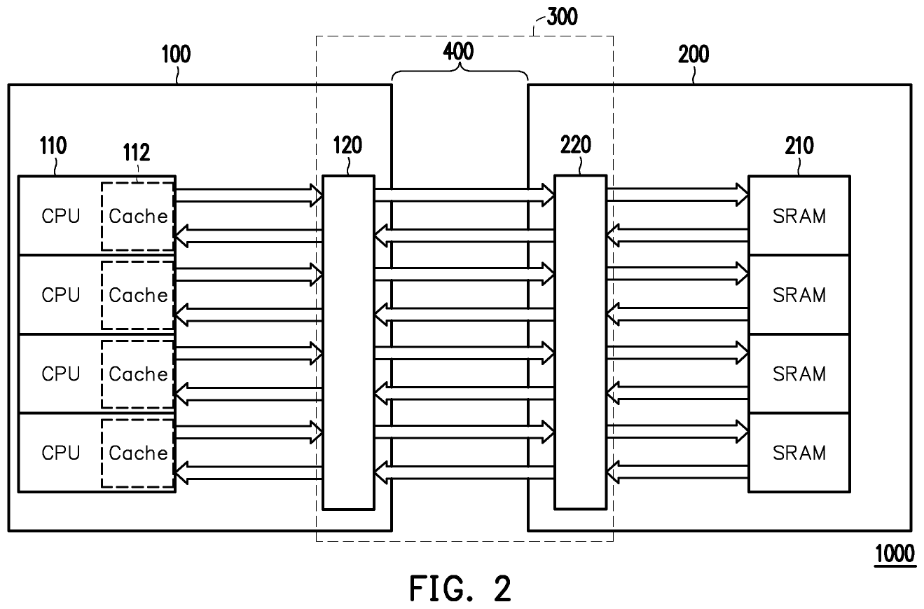

FIG. 2 schematically illustrates a communication mechanism of the interface between the first semiconductor die and an adjacent second semiconductor die, according to an embodiment of the invention. Referring to FIG. 2, the first semiconductor die 100 may include a function circuit 110 and a first interface circuit 120 implemented therein. The function circuit 110 with the cache blocks 112 in an example form a processor and is in signal communication to the first interface circuit 120. For example, the processor is connected to the first interface circuit 120 to transmit or receive signals through the first interface circuit 120, as intended to communicate with the second semiconductor die 200. The second semiconductor die 200 may include second function circuit 210 and a second interface circuit 220 implemented therein. The second function circuit 210 may include an SRAM circuit in signal communication to the second interface circuit 220 for communicating with the first semiconductor die 100. In addition, the first semiconductor die 100 and the second semiconductor die 200 are connected through the bonding structure 400 which achieve the physical and electrical connection between the first semiconductor die 100 and the second semiconductor die 200. In the embodiment, the first interface circuit 120, the second interface circuit 220 and the bonding structure 400 construct the interface 300 which establishes a bi-way connection for signal transmission between the first semiconductor die 100 and the second semiconductor die 200, and all signals are parallel transmitted or received by the interface 300.

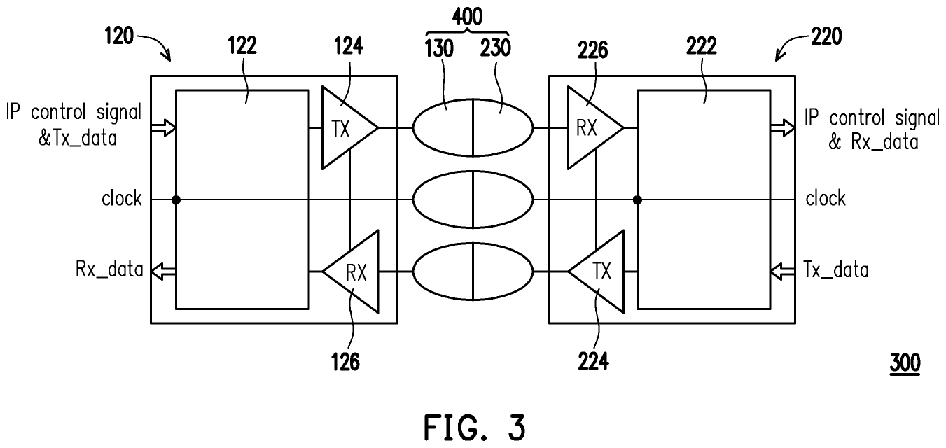

FIG. 3 schematically illustrates an interface interlinking between the first semiconductor die and an adjacent second semiconductor die, according to an embodiment of the invention. As shown in FIG. 3, the interface 300 includes the first interface circuit 120 implemented in the first semiconductor die 100 as indicated in FIG. 1 and the second interface circuit 220 implemented in the second semiconductor die 200 as indicated in FIG. 1 and the interface 300 further includes first bonding components 130 and second bonding components 230. The first bonding components 130 are disposed in the first semiconductor die 100, the second bonding components 230 are disposed in the second semiconductor die 200 and the first bonding components 130 are respectively bonded to the second bonding components 230 to serve as the bonding structure 400.

In the embodiment, referring FIG. 1 to FIG. 3, the first semiconductor die 100 includes the function circuit 110, the first interface circuit 120 and the first bonding components 130. The function circuit 110 may include the cache circuit 112 therein to serve as a processor circuit as described in FIG. 2. The first interface circuit 120, as shown in FIG. 3, includes an interface logic circuit 122, transceivers 124 and receivers 126. The transceivers 124 and the receivers 126 are connected to the first bonding components 130 in a one-to-one manner so as to establish the signal transmission to and/or from the second semiconductor die 200. In some embodiments, the interface logic circuit 122 is configured to provide a control logic for BIST (built-in self-test), training, repair, parity functions and DFT (Design-for-Testability) logic, or the like.

In some embodiments, the first interface circuit 120 include flip-flop (FF) units, multiplexers and other components for establishing the interlink circuit to the second semiconductor die 200. The multiplexer in an example is a double data rate (DDR) type in accordance with the input data at the flip-flop. As shown in FIG. 3, a single clock is provided through the first interface circuit 120 and the second interface circuit 220. The flip-flop and the multiplexer are controlled in timing by the single clock.

In some embodiments, the first interface circuit 120 may receive a commend as intended by the core circuit (e.g. the function circuit 110) of the first semiconductor die 100 and provide outputs to the second semiconductor die 200 through the transceiver 124 and the corresponding bonding component 130. The command in an example as an input may include a cluster of data Tx_data, a control signal such as IP control signal, and/or command without specific limitation. The command may also include a selecting slave identification, which is used to select the second semiconductor dies 200 to perform the command from the core circuit (e.g. the function circuit 110) of the first semiconductor die 100. The first interface circuit 120 may also receive the response from the second semiconductor die 200 through the corresponding bonding component 130 and the receiver 126, and then inwardly transmit the data Rx_data into the core circuit (e.g. the function circuit 110) of the first semiconductor die 100.

In the embodiment, referring FIG. 1 to FIG. 3, the second semiconductor die 200 includes the function circuit 210, the second interface circuit 220 and the second bonding components-230. The second function circuit 210 may include an SRAM circuit as described in FIG. 2. The second interface circuit 220, as shown in FIG. 3, includes an interface logic circuit 222, transceivers 224 and receivers 226. The receivers 226 in the second interface circuit 220 are connected to the corresponding transceivers 124 in the first interface circuit 120 through the correspond bonding components 130 and the corresponding bonding components 230. Similarly, the transceivers 224 in the second interface circuit 220 are connected to the corresponding receivers 126 in the first interface circuit 120 through the correspond bonding components 130 and the corresponding bonding components 230. In addition, the second interface circuit 220 is controlled in timing by the single clock. As shown in FIG. 3, the interface logic circuit 222 may output the response, such as the data Rx_data to another second semiconductor die 220 (as shown in FIG. 1) and receive the data Tx_data from said another second semiconductor die 220.

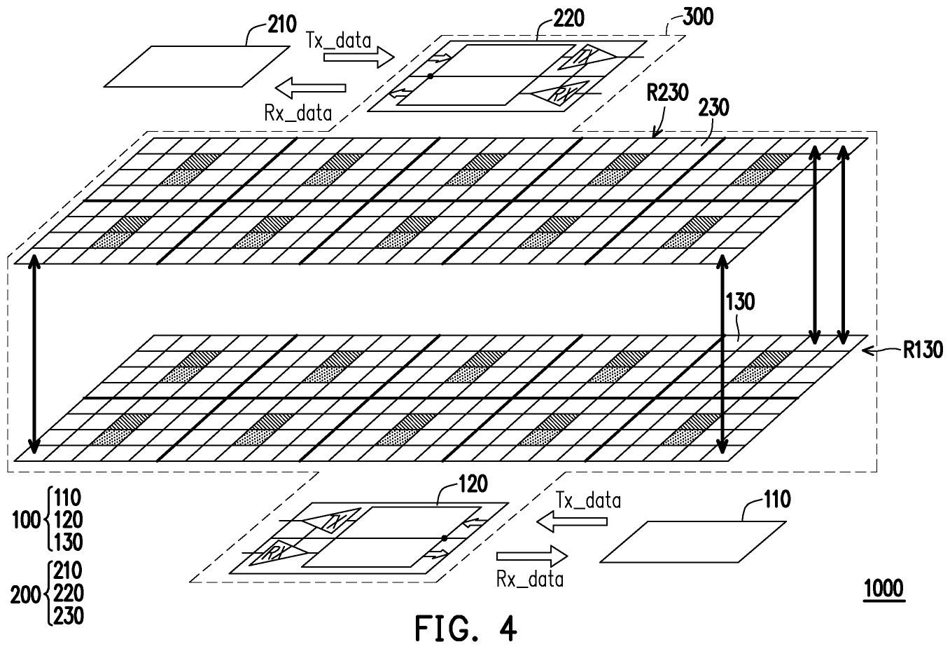

FIG. 4 schematically illustrates the arrangement of the interface for the semiconductor device in accordance with some embodiments of the disclosure. In FIG. 4, the semiconductor device 1000 includes the first semiconductor die 100 and the second semiconductor die 200. Specifically, the first semiconductor die 100 and the second semiconductor die 200 are interlined by the interface 300. The first semiconductor die 100 may include the function circuit 110, the first interface circuit 120 and the first bonding components 130. The second semiconductor die 200 may include the function circuit 210, the second interface circuit 220 and the second bonding components 230. FIG. 4 intends to present the arrangements of the components of the interface 300, while the arrangements of the function circuit 110 and the function circuit 210 are not limited to the relationship shown in the drawings.

In the embodiment, the first bonding components 130 may be arranged in a prescribed pitch that is determined based on the bonding technique. Specifically, the first bonding components 130 are arranged in a first bond array region R130. The first interface circuit 120 is arranged in a region with a determined area smaller than the first bonding array region R130 and is substantially completely located inside the first bonding array region R130. As described in above, the first bonding components 130 are connected to the transceivers 124 and the receivers 126 in the first interface circuit 120 in a one-to-one manner, and a pitch of the transceivers 124 and the receivers 126 may be smaller than a pitch of the first bonding components 130. In some embodiments, a portion of the first interface circuit 120 overlaps one or more of the first bonding components 130. In the embodiment, the function circuit 110 is in signal communication to the first interface circuit 120. In some embodiments, a portion of the function circuit 110 may be arranged inside the first bonding array region R130 and/or may overlap one or more of the first bonding components 130.

The second bonding components 230 may be arranged in a prescribed pitch that is determined based on the bonding technique. Specifically, the second bonding components 230 are arranged in a second bond array region R230. The second bonding components 230 may be arranged corresponding to the first bonding components 130 so that the second bond array region R230 is substantially mirrored from the first bond array region R130. Therefore, the second bonding components 230 are connected to the first bonding components 130 in a one-to-one manner. The second interface circuit 220 is arranged in a region with a smaller area than the second bonding array region R230 and is substantially completely located inside the second bonding array region R230. As described in above, the second bonding components 230 are connected to the transceivers 224 and the receivers 226 in the second interface circuit 220 in a one-to-one manner. A pitch of the transceivers 224 and the receivers 226 may be smaller than a pitch of the second bonding components 230. In some embodiments, a portion of the second interface circuit 220 overlaps one or more of the second bonding components 230. In the embodiment, the function circuit 210 is in signal communication to the second interface circuit 220. In some embodiments, the arrangement of the function circuit 210 may be arranged inside the second bonding array region R230 and/or may overlap one or more of the second bonding components 230.

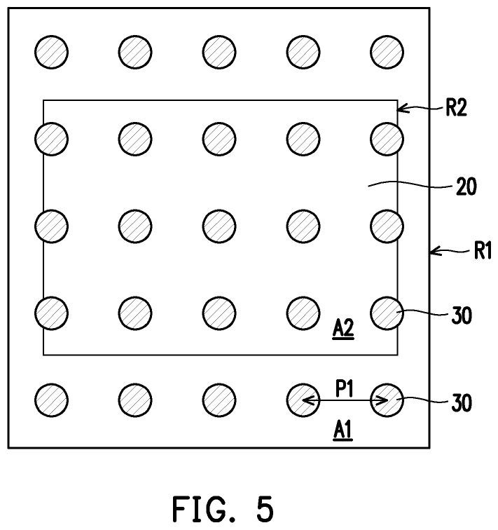

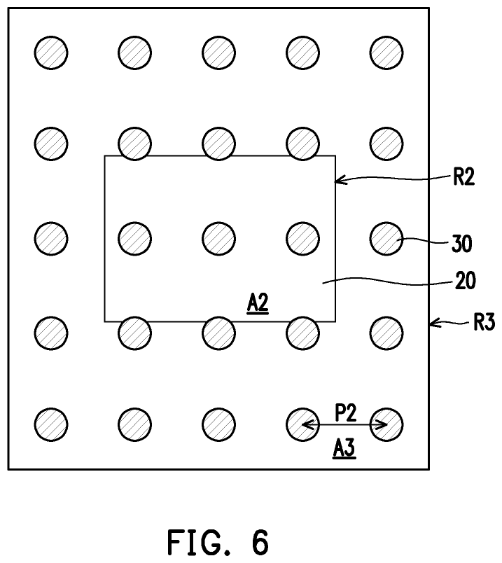

In some embodiments, the arrangement region of the first interface circuit 120 may be independent from the arrangement of the first bonding component 130 and the arrangement region of the second interface circuit 220 may be independent from the arrangement of the second bonding component 230. For example, FIG. 5 and FIG. 6 schematically illustrate the arrangements of the interface circuit and the bonding components in accordance with some embodiments of the disclosure. In FIG. 5, the interface circuit 20 may refer to the first interface circuit 120 or the second interface circuit 220 in the previous embodiment, the bonding components 30 may refer to the first bonding components 130 or the second bonding components 230 in the previous embodiments and the bonding array region R1 may refer to the first bonding array region R130 or the second bonding array region 230 in the previous embodiments. The bonding components 30 are arranged in a pitch P1 in a 5×5 array and the bonding components 30 are arranged in the bonding array region R1 that has an area A1. The interface circuit 20 is arranged in a prescribed region R2 that has an area A2. As described in the previous embodiments, the interface circuit 20 may include an interface logic circuit, transceivers and receivers that may be fabricated using nano or smaller level semiconductor manufacturing process. Therefore, the physical implement of the interface circuit 20 requires a small space. As shown in FIG. 5, the area A2 is smaller than the area A1. In the embodiment, the interface circuit 20 is completely arranged inside the bonding array region R2. In some embodiments, other circuits may be arranged at the space between the boundary of the area A2 and the boundary of the area A1 to optimize the spacing utility of the semiconductor device.

In another embodiment as shown in FIG. 6, the bonding components 30 are arranged in a pitch P2 in a 5×5 array and the bonding components 30 are arranged in the bonding array region R3 that has an area A3. Comparing FIG. 5 and FIG. 6, the pitch P2 is larger than the pitch Pl and the area A3 is greater than the area A2, but the interface circuit 20 remains arranged in the prescribed region R2 that has an area A2. It is noted that the interface circuit 20 may be applicable in various designs of the bonding array region without rearranging the components in the interface circuit 20. In other words, the arrangement of the interface circuit 20 may be independent from the arrangement of the corresponding bonding components 30. In some embodiments, other circuits may be arranged at the space between the boundary of the area A2 and the boundary of the area A3 to optimize the spacing utility of the semiconductor device.

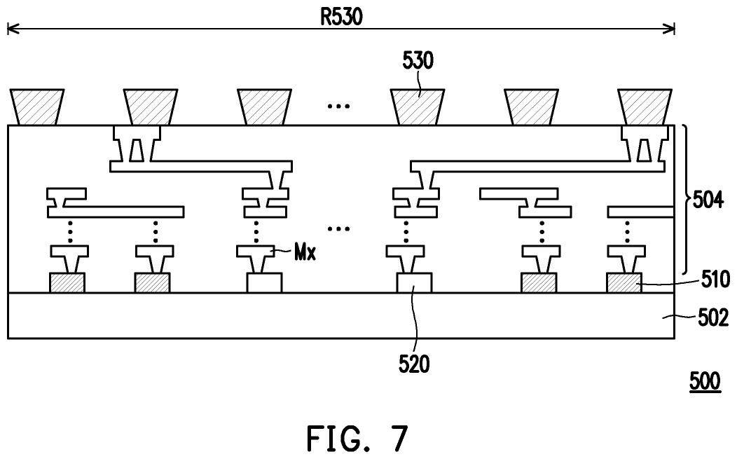

FIG. 7 schematically illustrates a portion of a semiconductor die in a cross-section view in accordance with some embodiments of the disclosure. As shown in FIG. 7, a semiconductor die 500 includes a substrate 502, electronic components for a function circuit 510, electronic components for an interface circuit 520, bonding components 530 and an interconnect wiring structure 504. The substrate 502 may be a semiconductor substrate or a semiconductor substrate inclusive of isolation regions. The electronic components for the function circuit 510 and the electronic components for the interface circuit 520 are formed in the substrate 502. The bonding components 530 are electrically connected to the electronic components in the interface circuit 520 through the interconnect wiring structure 504.

The electronic components for the function circuit 510 and the electronic components for the interface circuit 520 may include active components such as transistors or the like, passive components such as capacitors, resistors or the like, or a combination thereof. In some embodiments, the electronic components for the function circuit 510 and the electronic components for the interface circuit 520 may be partially integrated in the substrate 502 and fabricated by using nano level or smaller semiconductor manufacturing process.

The interconnect wiring structure 504 include multiple metal layers Mx and multiple intervening dielectric layers to establish the required electrical transmission paths for the electronic components for the function circuit 510 and the electronic components for the interface circuit 520. In some embodiments, the bonding components 530 include bonding pads that are optionally fabricated by the same method of forming the metal layers Mx in the interconnect wiring structure 504. In some embodiments, the bonding components 530 include micro bumps that is formed in a form of a conductor ball/pillar or the like.

In the embodiment, a portion of the electronic components of the interface circuit 520 is electrically connected to the corresponding bonding components 530 through the interconnect wiring structure 504 and such electronic components includes transceivers and receivers. In some embodiments, a portion of the electronic components of the interface circuit 520 overlaps one or more of the bonding components 530. Specifically, the bonding components 530 are arranged in a bond array region R530 and the interface circuit 520 is arranged inside the bond array region R530. The interface circuit 520 occupies a smaller area than the bond array region R530 and the region between the outer most component of the interface circuit 520 and the boundary of the bond array region R530 may be used by other chip level placement and routing to optimize the spacing utility of the substrate 502.

The function circuit 510 may be disposed beside the interface circuit 520 and a portion of the function circuit 510 may be located inside the bond array region R530. In some embodiments, a portion of the electronic components of the function circuit 510 overlaps one or more of the bonding components 530. The function circuit 510 may be in signal communication to the interface circuit 520 so that the electric signal from the function circuit 510 may be transmitted to the bonding component 530 through the interface circuit 520 and the signal input from the bonding component 530 may be transmitted to the function circuit 510 through the interface circuit 520.

The interconnect wiring structure 504 includes multiple metal layers Mx that establish staggered signal transmission path between the electronic components of the interface circuit 520 and the bonding components 530. The arrangement of the electronic components of the interface circuit 520 may be independent from the arrangement of the corresponding bonding components 530. For example, when viewed from the top view, the electronic component (transceiver or receiver) of the interface circuit 520 and the corresponding bonding component 530 that are used for transmitting the same signal may be located at two separate positions and other components (transceiver or receiver) of the interface circuit 520 and/or bonding components 530 may be located between the two separate positions. In alternative embodiments, two adjacent electronic components (transceiver or receiver) of the interface circuit 520 may be spaced by a pitch that is smaller than the pitch of two corresponding bonding components 530 connecting thereto.

The structure of the semiconductor die 500 may be considered as an implemental example of the first semiconductor die 100 or the second semiconductor die 200 that are described in the previous embodiments. For example, the function circuit 510 may be an implemental example of the function circuit 110 or the function circuit 210 shown in FIGS. 2 to 4, the interface circuit 520 may be an implemental example of the first interface circuit 120 or the second interface circuit 220 shown in FIGS. 2 to 4, and the bonding components 530 may be an implemental example of the first bonding components 130 or the second bonding component 230 shown in FIG. 3. Accordingly, the interface circuit 520 and the bonding components 530 may be a part of the interface 300 depicted in FIGS. 1 to 4. In addition, the arrangement of the interface circuit 20 and the bonding components 30 depicted in FIGS. 5 and 6 may be applicable to the structure of the semiconductor die 500 so that the interface circuit 520 is compatible to various designs of bond array.

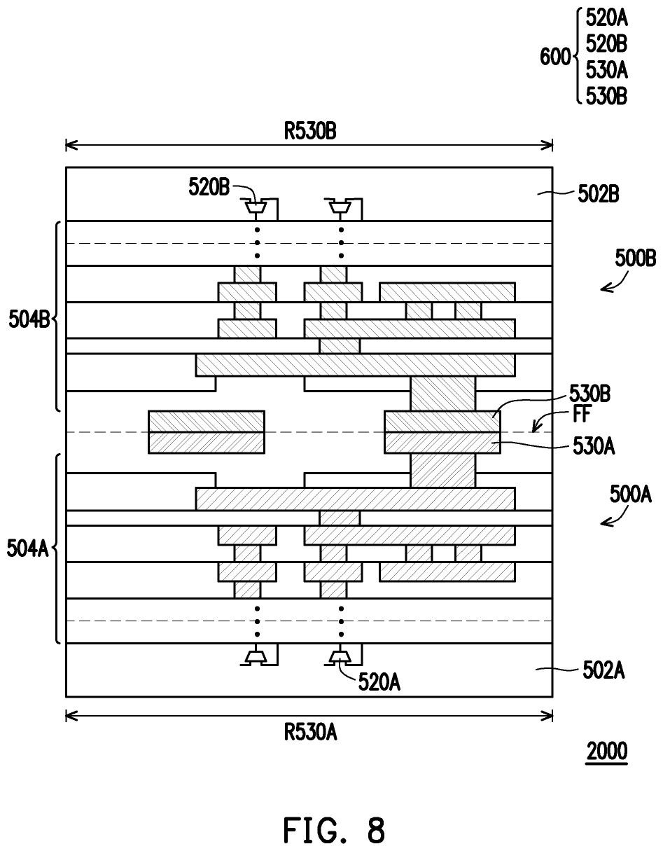

FIG. 8 schematically illustrates a semiconductor device in a cross-sectional view in accordance with some embodiments of the disclosure. A semiconductor device 2000 includes a first semiconductor die 500A and a second semiconductor die 500B that are bonded to each other in a face-to-face manner. Each of the first semiconductor die 500A and the second semiconductor die 500B may be similar to the semiconductor die 500 depicted in FIG. 7 and thus the descriptions for the components of the semiconductor die 500 in FIG. 7 are applicable to the corresponding components of the semiconductor device 2000.

The first semiconductor die 500A includes a first substrate 502A, a first interface circuit 520A and first bonding components 530A, wherein the first bonding components 530A are arranged in a first bond array region R530A and the first interface circuit 520A is arranged inside the first bond array region R530A. Specifically, the first semiconductor die 500A further includes an interconnect wiring structure 504A located between the first interface circuit 520A and the first bonding components 530A. The interconnect wiring structure 504A includes metal layers establishing the signal transmission paths between the first interface circuit 520A and the first bonding components 530A.

The second semiconductor die 500B includes a second substrate 502B, a second interface circuit 520B and second bonding components 530B, wherein the second bonding components 530B are arranged in a second bond array region R530B and the second interface circuit 520B is arranged inside the second bond array region R530B. Specifically, the second semiconductor die 500B further includes an interconnect wiring structure 504B located between the second interface circuit 520B and the second bonding components 530B. The interconnect wiring structure 504B includes metal layers establishing the signal transmission paths between the second interface circuit 520B and the second bonding components 530B.

In the embodiment, the first semiconductor die 500A is oriented that the front side (the side implemented with circuits) faces up, and the second semiconductor die 500B is oriented that the front side (the side implemented with circuits) faces down. The second bond array region R530B is substantially mirrored from the first bond array region R530A, and the first bonding components 530A are connected to the second bonding components 530B in a one-to-one manner. In the bonded structure as shown in FIG. 8, the first interface circuit 520A and the second interface circuit 520B are located between the first substrate 502A and the second substrate 502B, which is understood as a face-to-face bonded structure.

In the embodiment, the first bonding components 530A and the second bonding components 530B are bonding pads. The bonding face FF is formed by the first bonding components 530A in contact with the second bonding components 530B and the dielectric surrounding the first bonding components 530A in contact with the dielectrics surrounding the second bonding components 530B. In some alternative embodiments, the first bonding components 530A and the second bonding components 530B may be micro bumps or other types of 3D interconnection components and an underfill may be further disposed between the first semiconductor die 500A and the second semiconductor die 500B to surround the bonded structure formed by the first bonding components 530A connecting to the second bonding components 530B.

In the embodiment, the first semiconductor die 500A and the second semiconductor die 500B are interlinked by an interface 600 constructed by the first interface circuit 520A, the first bonding components 530A, the second interface circuit 520B and the second bonding components 530B. The interface 600 is considered as a 3D interlink technique for signal communication between semiconductor dies in a 3D stacking structure. The interface 600 may have a similar design to the interface 300 depicted in the previous embodiments.

In some embodiments, the first semiconductor die 500A may be an implemental example of the first semiconductor die 100 shown in FIGS. 1-4. Referring to the previous embodiments, the first interface circuit 520A may include the interface logic circuit 122, the transceivers 124 and the receivers 126 shown in FIG. 3. The transceivers and the receivers in the interface circuit 520A are electrically connected to the first bonding components 530A, respectively. In addition, the first bonding components 530A may be arranged in an array similar to the array shown in FIGS. 5 and 6, but the disclosure is not limited thereto. The interface logic circuit, the transceivers and the receivers in the interface circuit 520A may be arranged inside the first bond array region R530A. In some embodiments, a pitch of the transceivers and the receivers in the interface circuit 520A may be smaller than a pitch of the first bonding components 530A. In some embodiments, a portion of the first interface circuit 520A overlaps one or more of the first bonding components 530A. In some embodiments, the arrangement of the transceivers and the receivers in the interface circuit 520A may be independent from the arrangement of the first bonding components 530A.

In some embodiments, the second semiconductor die 500B may be an implemental example of the second semiconductor die 200 shown in FIGS. 1-4. Referring to the previous embodiments, the second interface circuit 520B may include the interface logic circuit 222, the transceivers 224 and the receivers 226 shown in FIG. 3. The second bonding components 530B may be arranged in an array similar to the array shown in FIGS. 5 and 6, but the disclosure is not limited thereto. The second interface circuit 520B is arranged inside the second bond array region R530B. The interface logic circuit, the transceivers and the receivers in the second interface circuit 520B are arranged inside the second bond array region R530B. The transceivers and the receivers in the second interface circuit 520B are electrically connected to the second bonding components 530B, respectively. A pitch of the transceivers and the receivers in the second interface circuit 520B is smaller than a pitch of the second bonding components 530B. A portion of the second interface circuit 520B overlaps one or more of the second bonding components 530B.

In some embodiments, a method of arranging the interface 600 of the semiconductor device 2000 may include providing a first bond array region R530A for arranging first bonding components 530A implemented in a first semiconductor die 500A. In some embodiments, the first bond array region R530A may be determined based on the prescribed pitch rule of arranging the first bonding components 530A. For example, the first bond array region R530A is provided for arranging the first bonding components 530A in a pitch ranged from 6 microns to 16 microns, but the disclosure is not limited thereto. In other alternative embodiments, the pitch of the first bonding components 530A may be determined based on the design of the products.

Subsequently, the method further provides a first interface circuit 520A implemented inside the first bond array region R530A in the first semiconductor die 500A. The first interface circuit 520A may include interface logic circuit, transceivers and receivers that are fabricated using the semiconductor manufacturing process and the electronic components in the first interface circuit 520A may have small sizes at about nano level. Generally, the sizes and the connection relationships of the electronic components in the first interface circuit 520A are determined in advance so that the area for arranging the interface circuit 520A is determined.

In the embodiment, the first interface circuit 520A is electrically to the corresponding first bonding components 530A through the interconnect wiring structure 504A shown in FIG. 8 and the interconnect wiring structure 504A is able to provide detours for signal transmission. Therefore, the first interface circuit 520A is arranged inside the first bond array region R530A without considering the relative positions of the first bonding components 530A. In addition, the same specification on sizes and the connection relationships of the electronic components in the first interface circuit 520A is compatible for various pitch designs of the first bonding components 530A, which provides a flexible design rule for fabricating the first semiconductor die 500A of the semiconductor device 2000. Since the first interface circuit 520A requires only a small area, the substrate may have more space for arranging other circuits or components, which improves the design flexibility of the semiconductor device 2000.

The method also includes providing a second interface circuit 520B and second bonding components 530B implemented in a second semiconductor die 500B. Similar to the first semiconductor die 500A, the second bonding components 530B in the second semiconductor die 500B may be arranged in a second bond array region R530B and the second interface circuit 520B in the second semiconductor die 500B may be arranged inside the second bond array region R530B. In addition, the arrangement of the second interface circuit 520B may be independent from the arrangement of the second bonding components 530B. Therefore, the same specification on sizes and the connection relationships of the components in the second interface circuit 520B is compatible for various pitch designs of the second bonding components 530B. In some embodiments, the second bond array region R530B may be provided for arranging the second bonding components 530B in a pitch ranged from 6 microns to 16 microns, but the disclosure is not limited thereto. In other alternative embodiments, the pitch of the second bonding components 530B may be determined based on the design of the products.

The method also includes bonding the first bonding components 530A to the second bonding components 530B. In the embodiments, the second bond array region R530B may be substantially mirrored from the first bond array region R530A and the first semiconductor die 500A and the second semiconductor die 500B are bonded in a face-to-face manner. As depicted in FIG. 8, the first semiconductor die 500A further includes the interconnect wiring structure 504A that establishes detour for signal transmission and thus the arrangement of the first interface circuit 520A may be independent from the arrangement of the first bonding components 530A. Similarly, the second interface circuit 520B is electrically connected to the second bonding components 530B through the interconnect wiring structure 504B in the second semiconductor die 500B and the arrangement of the second interface circuit 520B may be independent from the second bonding components 530B.

In view of the above, the semiconductor device in accordance with some embodiments of the disclosure includes multiple semiconductor dies bonded in a face-to-face manner. The interface interlinking between the semiconductor dies includes an interface circuit and bonding components formed in each of the semiconductor die. The interface circuit may be arranged in a determined region which is compatible to various pitch designs of the bonding components. Accordingly, the arrangement of the interface is flexible. In addition, the interface circuit is concentrated within the determined region so that the substrate implemented with the interface circuit may have flexible spacing utility.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A semiconductor device, comprising:
a first semiconductor die comprising a first substrate, a first interface circuit and first bonding components, wherein the first bonding components are arranged in a first bond array region and the first interface circuit is arranged inside the first bond array region; and
a second semiconductor die comprising a second substrate, a second interface circuit and second bonding components, wherein the first bonding components are connected to the second bonding components, the first interface circuit and the second interface circuit are located between the first substrate and the second substrate, and the first semiconductor die and the second semiconductor die are interlinked by an interface constructed by the first interface circuit, the first bonding components, the second interface circuit and the second bonding components.

2. The semiconductor device of claim 1, wherein the first interface circuit comprises an interface logic circuit, transceivers and receivers, and the interface logic circuit, the transceivers and the receivers are arranged inside the first bond array region.

3. The semiconductor device of claim 2, wherein the transceivers and the receivers are electrically connected to the first bonding components, respectively.

4. The semiconductor device of claim 2, wherein a pitch of the transceivers and the receivers is smaller than a pitch of the first bonding components.

5. The semiconductor device of claim 1, wherein a portion of the first interface circuit overlaps one or more of the first bonding components.

6. The semiconductor device of claim 1, wherein the first semiconductor die further comprises function circuit, the function circuit is in signal communication to the first interface circuit.

7. The semiconductor device of claim 6, wherein a portion of the function circuit is arranged inside the first bond array region.

8. The semiconductor device of claim 1, wherein the first semiconductor die further comprises an interconnect wiring structure disposed between the first bonding components and the first interface circuit.

9. The semiconductor device of claim 1, wherein the first bonding components and the second bonding components comprises bonding pads, micro bumps or other types of 3D interconnection components.

10. The semiconductor device of claim 1, wherein the second bonding components are arranged in a second bond array region substantially mirrored from the first bond array region.

11. The semiconductor device of claim 10, wherein the second interface circuit is arranged inside the second bond array region.

12. The semiconductor device of claim 10, wherein the second interface circuit comprises an interface logic circuit, transceivers and receivers, and the interface logic circuit, the transceivers and the receivers are arranged inside the second bond array region.

13. The semiconductor device of claim 12, wherein the transceivers and the receivers are electrically connected to the second bonding components, respectively.

14. The semiconductor device of claim 12, wherein a pitch of the transceivers and the receivers is smaller than a pitch of the second bonding components.

15. The semiconductor device of claim 1, wherein a portion of the second interface circuit overlaps one or more of the second bonding components.

16. The semiconductor device of claim 1, wherein the second semiconductor die further comprises a function circuit, and the function circuit is in signal communication to the second interface circuit.

17. The semiconductor device of claim 16, wherein a portion of the function circuit is arranged inside a second bond array region of the second bonding components.

18. The semiconductor device of claim 1, wherein the second semiconductor die further comprises an interconnect wiring structure disposed between the second bonding components and the second-interface circuit.

19. A method of arranging an interface of a semiconductor device, comprising:
providing a first bond array region for arranging first bonding components implemented in a first semiconductor die;
providing a first interface circuit implemented inside the first bond array region in the first semiconductor die;
providing a second interface circuit and second bonding components implemented in a second semiconductor die; and
bonding the first bonding components to the second bonding components.

20. The method of claim 19, wherein the first interface circuit comprises an interface logic circuit, transceivers and receivers, and the interface logic circuit, the transceivers and the receivers are arranged inside the first bond array region.

21. The method of claim 20, wherein the transceivers and the receivers are electrically connected to the first bonding components, respectively, and a pitch of the transceivers and the receivers is smaller than a pitch of the first bonding components.

22. The method of claim 19, wherein the second bonding components are arranged in a second bond array region substantially mirrored from the first bond array region.

23. The method of claim 22, wherein the second interface circuit comprises an interface logic circuit, transceivers and receivers, and the interface logic circuit, the transceivers and the receivers are arranged inside the second bond array region.

24. The method of claim 23, wherein the transceivers and the receivers are electrically connected to the second bonding components, respectively, and a pitch of the transceivers and the receivers is smaller than a pitch of the second bonding components.

25. The method of claim 19, further providing a function circuit to be implemented inside the first bond array region in the first semiconductor die.

26. The method of claim 19, further providing a function circuit implemented in the second semiconductor die.
